(19) United States
(12) Patent Application Publication
(10) Pub. No.: US 2006/0273458 A1
(43) Pub. Date: Dec. 7, 2006

(54) Substrate structure of semiconductor package

(76) Inventors: Wen-Shien Huang, Hsin-chu (TW); E-Tung Chou, Hsin-chu (TW)

Correspondence Address: Mr. Joseph A. Sawyer, Jr.;SAWYER LAW GROUP LLP, Suite 406, 2465 East Bayshore Road, Palo Alto, CA, 94303, US

(21) Appl. No.: 11/447,526

(22) Filed: Jun. 5, 2006

(30) Foreign Application Priority Data
Jun. 7, 2005 (TW) 094118705

(51) Int. Cl. H01L 23/48

(52) U.S. Cl. 257/734

(57) ABSTRACT

A substrate structure of a semiconductor package is proposed. The structure includes a substrate with at least one opening; a grounding ring formed on the substrate and around the opening; and a plurality of plating through holes (PTH) formed in the substrate and corresponding to the grounding ring. The grounding area is increased by the grounding ring, so that the grounding quality of the substrate in package is improved. Meanwhile, it also simplifies the process, increases process yield and reduces cost of the process.

### CROSS-REFERENCE TO RELATED APPLICATIONS

This application claims benefit under 35 USC 119 of Taiwan Application No. 094118705, filed on Jun. 7, 2005.

### FIELD OF THE INVENTION

The present invention relates to substrate structures of semiconductor packages, and more particularly to a substrate structure of a cavity-down ball grid array (CDBGA) package.

### BACKGROUND OF THE INVENTION

As the electronic industry continues to grow rapidly, electronic products have gradually moved to the direction of multi-functionality and high performance. However, as the semiconductor packages move to the direction of highly integration and miniaturization, generated heat from the semiconductor chip during operation increases dramatically. If the generated heat from the semiconductor chip cannot be readily dissipated, the electronic performance and usage lifetime would be seriously impaired. Moreover, as typical semiconductor devices usually lack of shielding, the semiconductor device may easily be interfered by outside magnetic or external noises, therefore might seriously influencing its operation.

Referring to FIG. 1, in order to solve the foregoing problems, the industry has proposed a cavity-down ball grid array package. This type of conventional package comprises a substrate 10, a heat sink 12, at least one semiconductor chip, a plurality of bonding wires 14, an encapsulant 15 and a plurality of soldering balls 16.

The substrate 10 has a front surface 10a, a back surface 10b and at least one opening 101 whereon a grounding ring 11 is defined at the region around the side wall of the opening 101 of the substrate and a Ni/Au layer 110 is formed on the side wall of the opening 101 so as to increase the grounding area and protect the grounding metallic surface from oxidation damages. The grounding ring 11 therefore provides 11 a shielding effect to protect the semiconductor chip from outside noise. The heat sink 12 is made of a high conductive material such as cupper and is attached to the front surface 10a of the substrate 10, resulting in a cavity-down opening 101. The semiconductor chip 13 has an active surface 13a and a non-active surface 13b. Electrode pads are formed on the active surface 13a of the semiconductor chip 13 and the semiconductor chip 13 is positioned within the opening 101 of the substrate 10 and attached to the heat sink 12 via its non-active surface 13b in an upside down manner. A wire bonding process is then performed to electrically connect the electrode pads 131 with the electrical connection pads 17 on the surface of the substrate 10 and the grounding ring 11 via bonding wires 14, followed by an encapsulating process to form an encapsulant 15 to completely cover the semiconductor chip 13 and the bonding wires 14. Then, solder balls are implanted on the back side 10b of the substrate, which completes the process of forming a CDBGA package.

However, the prior art method of electroplating a Ni/Au layer on the side wall of the opening 101 of the substrate to increase the grounding surface and protect the grounding metallic surface of the grounding ring 11 from oxidation has a few disadvantages. These include difficulty in controlling the quality of Ni/Au layer and complication in the fabricating process to form Ni/Au layer on the side wall of the opening of the substrate, thereby making it not less than ideal, regarding to productivity and economical aspects. Moreover, large amount of chemicals are involved to form Ni/Au layers, which may cause gold contamination on the surface, leading to low yield of final products.

As a result, there is an urgent need to develop a substrate structure of a semiconductor package, in which the problems of difficulty in controlling the quality of Ni/Au layer, complication in fabricating process, low productivity and low economical benefit resulted from applying Ni/Au material on the side wall of the opening of the substrate adopted by the prior art can be solved.

### SUMMARY OF THE INVENTION

Accordingly, a primary objective of the present invention is to provide substrate structure for improving grounding quality.

Another objective of the invention is to provide a substrate structure for simplifying fabricating cost and lowering production cost.

Still another objective of the invention is to provide a substrate structure wherein contamination the surface of a final product with copper can be prevented.

Further another objective of the invention is to provide a substrate structure with enhanced fabricating yield and productivity and has more economical benefits.

In order to achieve the foregoing and other objectives, the substrate structure of a semiconductor package comprising: a substrate having a first surface and a second surface opposing to the second surface, in which the substrate has at least one opening penetrating through the first and second surface thereof; grounding ring formed on the first surface of the substrate around the opening; and at least one plating through holes, formed in the substrate at the position corresponding to the grounding ring. The substrate structure further comprises a heat sink attached to the to the second surface of the substrate so that one end of the opening is sealed off. The above mentioned conductive through hole is formed in the substrate at the position corresponding to the non-wire bonding region of the grounding ring.

Then, a semiconductor chip is positioned within the opening of the substrate and attached to the heat sink, in such a way that the semiconductor chip is accommodated within he opening of the substrate and electrically connected to the electrical connection pads, grounding ring via the bonding wires. This is then followed by forming an encapsulant to cover the semiconductor chip and the bonding wires and then implanting a plurality of solder balls on the first surface of the substrate, allowing the substrate of the semiconductor package to be electrically connected to the outside electronic device.

In comparison to the conventional technology, the substrate structure of the semiconductor package of the invention involves forming a plurality of openings in advance in the substrate at the positions corresponding to the grounding rings, followed by forming metallic layer in each opening, for increasing grounding areas as well as providing with preferable electronic functionality for the semiconductor chip which is subsequently positioned within the opening of the substrate.

Besides, regarding to the substrate structure of the semiconductor package of the invention, forming a plurality of openings in the substrate at the positions corresponding to the non-wire bonding region of the grounding rings, followed by forming metallic layer in each opening for increasing grounding area (2πrh wherein r is radius of the opening and h is the depth of the opening) is advantageous because there is no need to form a Ni/Au layer on the side wall of the opening of the substrate as described in the prior art. As a result, the fabricating process is simplified and the production cost is reduced, while the yield is increased and the drawbacks experienced in the prior art by adopting the method of forming Ni/Au layer on the side wall of the substrate, such as complication in fabricating process, low fabricating yield, high production cost and large amount of contamination of the final product with gold can be all solved.

### BRIEF DESCRIPTION OF THE DRAWINGS

The present invention can be more fully understood by reading the following detailed description of the preferred embodiments, with reference made to the accompanying drawings, wherein:

FIG. 1 is a schematic cross-sectional view of a conventional CDBGA package;

FIG. 2A is a schematic cross-sectional view of a substrate structure of a preferred embodiment of the present invention;

FIG. 2B is 3D schematic view of the substrate structure of a preferred embodiment of the invention;

FIG. 3 is a schematic cross-sectional view of the substrate structure of FIG. 2A in the process of packaging semiconductor chip in the semiconductor package.

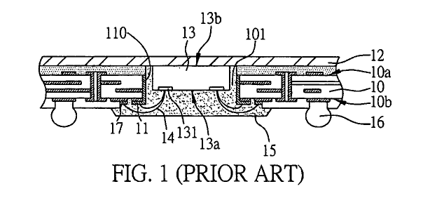

### DETAILED DESCRIPTION OF THE PREFERRED EMBODIMENTS

The present invention relates generally to substrate structures of semiconductor packages, and more particularly to a substrate structure of a cavity-down ball grid array (CDBGA) package. The following description is presented to enable one of ordinary skill in the art to make and use the invention and is provided in the context of a patent application and its requirements. Various modifications to the preferred embodiments and the generic principles and features described herein will be readily apparent to those skilled in the art. Thus, the present invention is not intended to be limited to the embodiments shown, but is to be accorded the widest scope consistent with the principles and features described herein.

The present invention is described in the following with specific embodiments, so that one skilled in the pertinent art can easily understand other advantages and effects of the present invention from the disclosure of the invention. The present invention may also be implemented and applied according to other embodiments, and the details may be modified based on different views and applications without departing from the spirit of the invention. Particularly, although in the drawings and descriptions of the invention, the substrate structure proposed by the invention is used in a cavity-down ball grid array (CDBGA) package to exemplify, it should be noted that this substrate structure of the invention could be widely used in many different types of semiconductor packages.

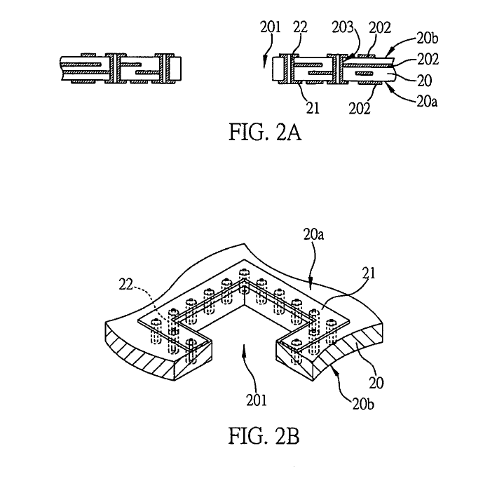

Referring to FIGS. 2A and 2B, a substrate structure of a preferred embodiment proposed by the present invention is described in details herein. As shown in the drawings, the substrate structure of a semiconductor package comprising: a substrate 20 having a first surface 20a, a second surface 20b opposing to the first surcease 20a and at one opening 201 penetrating the first and second surface 20a, 20b of the substrate; at least one grounding rings 21 forming on the first surface 20a of the substrate 20 around the periphery of the opening 201; and at least one conductive through hole formed within the substrate 20 corresponding to the position of grounding ring 21.

The substrate can be a circuit board with multiple circuit layers 202 and each circuit layer 202 can electrically connected via the plated through holes (PTH) 203 formed in the substrate.

The grounding rings 21 are formed on the first surface 20a of the substrate 20 and around the periphery of the opening 201.

The conductive through holes 22 are electrically connected to the grounding rings 21. The conductive through holes 22 are formed by drilling openings on non-wire bonding region of the substrate 20 at the positions corresponding to the grounding rings 21 and performing a plating process to form the conductive through holes 22, allowing the conductive through holes 22 to be electrically connected to the grounding rings 21. As a result, the grounding area (2πrh wherein r is radius of the opening and h is the depth of the opening) is increased, so that both productivity and fabricating yield are enhanced while the production cost is desirably reduced.

In addition, the substrate structure of the invention further comprises a heat sink, which is made of a high conductive material such as copper. The heat sink is attached to the second surface 20b of the substrate via an adhesion layer so as to seal off one end of the opening 201 forming a cavity with the downwardly facing opening.

In comparison to the conventional technology, the characteristic feature of the invention involves forming a plurality of conductive through holes 22 on the non-wire bonding region of the substrate 20 at the positions corresponding to the grounding rings so as to increase the grounding areas. This also provides a shielding for the chip, and has the advantages of simplifying fabricating process, enhancing yield, reducing fabricating cost, and preventing large amount of contamination of the final products with gold.

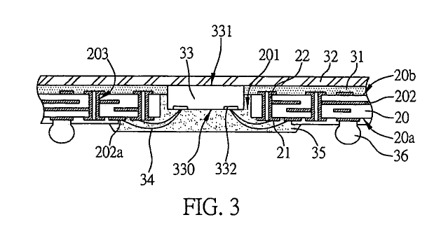

Referring to FIG. 3, a semiconductor package such as a CDBGA package using the substrate structure of the invention is described herein. The semiconductor package is formed by firstly attaching a heat sink on the second surface 20b of the substrate shown in FIG. 2 via an adhesive layer 31, so as to seal off one end of the opening 201. A semiconductor chip 33 is then attached on the heat sink 32 in the substrate opening 201. This is then followed by a series of fabricating process: wire bonding, encapsulating, and solder ball implanting processes to electrically connect the chip 33 to the substrate, form an encapsulant 35 for covering the chip 33 and the bonding wires, and implant solder balls 36 on the first surface 20a of the substrate, so as to form the semiconductor package.

The semiconductor chip 33 has an active surface 330 and an opposing non-active surface 331. The active surface 330 has a plurality of electrode pads 332. In the present embodiment, the active surface 331 of the semiconductor chip 33 is attached to the heat sink 32 via an adhesive layer 31 and accommodated within the opening 201 of the substrate. Besides, the heat generated from the semiconductor chip 33 during operation can be effectively dissipated directly through the heat sink to the ambiance, thereby extending the usage lifetime of the chip.

The bonding wires 34 are used to electrically connect the electrode pads 33 on the active surface 330 of the semiconductor chip with the circuits 202, which serve as electrical connection pads 202a on the first surface 20a of the substrate 20. The above-mentioned bonding wires 34 are gold wires and are disposed on the grounding ring 21 where the conductive through hole is not formed, so as to increase the grounding area via the conductive through holes 22, thereby improving electrical functions of the semiconductor chip 33.

The encapsulant 35 is used to encapsulate the semiconductor chip 33, grounding ring 21 and the bonding wires 34.

The solder balls 36 are implanted on the first surface 20a of the substrate, allowing the semiconductor package with a semiconductor chip 33 accommodated therein to be electrically connected to an external electronic device such as printed circuit board.

Accordingly, the substrate structure of the semiconductor package of the invention involves forming a plurality of openings in advance in the substrate at the positions corresponding to the grounding rings, followed by forming metallic layer in each opening, for increasing grounding areas as well as providing with preferable electronic functionality for the semiconductor chip which is subsequently positioned within the opening of the substrate.

Besides, regarding to the substrate structure of the semiconductor package of the invention, forming a plurality of openings in the substrate at the positions corresponding to the non-wire bonding region of the grounding rings, followed by forming metallic layer in each opening for increasing grounding area (2πrh wherein r is radius of the opening and h is the depth of the opening) is advantageous because there is no need to form a Ni/Au layer on the side wall of the opening of the substrate as described in the prior art. As a result, the fabricating process is simplified and the production cost is reduced, while the yield is increased and the drawbacks experienced in the prior art by adopting the method of forming Ni/Au layer on the side wall of the substrate, such as complication in fabricating process, low fabricating yield, high production cost and large amount of contamination of the final product with gold can be all solved.

Moreover, a semiconductor chip can be incorporated and packaged within the substrate structure though the processes of wire bonding, encapsulating and solder ball implanting, and can be electrically connected to external electronic device such as printed circuit board via the conductive elements (such as solder balls) implanted on the substrate surface. Meanwhile, heat generated from the semiconductor chip during operation can be effectively dissipated to the ambiance through the heat sink of the substrate.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

What is claimed is:

1. A substrate structure of a semiconductor package, comprising:
a substrate having a first surface, second surface opposing the first surface and at least one opening penetrating the first and second surfaces;
a grounding ring formed on the first surface of the substrate around the opening of the substrate; and
at least one conductive through hole formed in the substrate at the position corresponding to the grounding ring and electrically connected with the grounding ring.

2. The substrate structure of claim 1, wherein the conductive through hole is formed in the substrate underneath the non-wire bonding region of the grounding ring.

3. The substrate structure of claim 1 further comprising a heat sink attached on the second surface of the substrate so as to seal off one end of the substrate opening.

4. The substrate structure of claim 3, wherein a semiconductor chip can be attached to the heat sink in the substrate opening, allowing the semiconductor chip to be accommodated within the opening and electrically connected to the electrical connection pads and grounding ring of the substrate via bonding wires.

5. The substrate structure of claim 4, further comprising an encapsulant for covering the semiconductor chip, bonding wires and grounding ring.

6. The substrate structure of claim 4, wherein a plurality of solder balls are implanted on the first surface of the substrate.

7. The substrate structure of claim 3, wherein an adhesive layer is provided between the substrate and the heat sink.

8. The substrate structure of claim 1 further comprising plated through holes within the substrate for electrically connecting each of the circuit layers to another in the substrate.
